(19) United States
(12) Patent Application Publication
(10) Pub. No.: US 2018/0076375 A1
(43) Pub. Date: Mar. 15, 2018

(54) DISTRIBUTED THERMOELECTRIC MODULE WITH FLEXIBLE DIMENSIONS

(71) Applicant: Tempronics, Inc., Tucson, AZ (US)

(72) Inventors: Tarek Makansi, Tucson, AZ (US); Michael Sato, Tucson, AZ (US); Kevin Forbes, Tucson, AZ (US)

(21) Appl. No.: 15/662,534

(22) Filed: Jul. 28, 2017

Related U.S. Application Data
(63) Continuation of application No. PCT/US2016/017603, filed on Feb. 11, 2016.
(60) Provisional application No. 62/115,469, filed on Feb. 12, 2015.
(60) Provisional application No. 62/133,208, filed on Mar. 13, 2015.

(51) Int. Cl. H01L 35/32; H01L 25/04

(52) U.S. Cl. CPC H01L 35/32; H01L 35/20; H01L 25/04

(57) ABSTRACT

A thermoelectric module pumps heat reversibly from one side to another side when energized with a voltage. The dimensions of the module may be configurable, allowing the thermal management area to be matched to the thermal load. The thickness of the module may be compressible, allowing for vibrational and clamped environments. The thermal connections of the module may allow for thermal expansion and contraction without physically stressing the thermoelectric elements.

### CROSS-REFERENCE

This application is a continuation of PCT Application Serial No. PCT/US2016/017603, filed Feb. 11, 2016, which claims priority to U.S. Provisional Application Ser. No. 62/115,469, filed Feb. 12, 2015, and U.S. Provisional Application Ser. No. 62/133,208, filed Mar. 13, 2015, each of which is entirely incorporated herein by reference.

### BACKGROUND

The thermoelectric effect is the conversion of temperature differences to electric voltage and vice versa. A thermoelectric device may create voltage when there is a temperature gradient across the thermoelectric device, such as when there is a different temperature on each side of the thermoelectric device. Conversely, when a voltage is applied to the thermoelectric device, it may create a temperature difference. An applied temperature gradient may cause charge carriers in the thermoelectric device to diffuse from a hot side to a cold side of the thermoelectric device.

The term “thermoelectric effect” encompasses the Seebeck effect, Peltier effect and Thomson effect. Solid-state cooling and power generation based on thermoelectric effects typically employ the Seebeck effect or Peltier effect for power generation and heat pumping. The utility of such conventional thermoelectric devices is, however, typically limited by their low coefficient-of-performance (COP) (for refrigeration applications) or low efficiency (for power generation applications).

Thermoelectric modules may contain densely packed elements spaced apart by 1-3 mm. Up to 256 such elements may be connected in an array that is 2×2 inches (5.08×5.08 cm) in area. When these modules are deployed, large and heavy heat sinks and powerful fans may be required to dissipate or absorb heat on each side. Small elements with low resistance may allow larger current (I) to flow before the resistive heat (I²R) generated destroys the thermoelectric cooling. The use of short elements for maximum cooling capacity results in the hot and cold side circuit boards being close together. This proximity may result in the high density.

To achieve low density packing of thermoelectric elements, the elements may be laterally spaced on the boards, but then the backflow of heat conducted and radiated through the air between the elements limits the overall performance some designs may require evacuating the module interior to reduce heat backflow due to air conduction, but vacuum cavities require expensive materials and are prone to leaks. Vacuum materials (like glass and Kovar™) are also hard and easily broken when thin enough to limit their own backflow of heat. Broken glass can lead to safety issues when these modules are used in seat cushions, automobiles, and other environments.

Another disadvantage of the prior art design of thermoelectric modules is that the high density of heat moved to the hot side may result in a temperature gradient through the heat sink, and this temperature change may subtract from the overall cooling that the module can achieve. In particular, traditional thermoelectric products may not be able to reach true refrigeration temperature because of this temperature gradient.

In addition, because some traditional thermoelectric modules may be placed in a solder reflow oven during assembly, only high-temperature materials may be used. Unfortunately, many desired uses of cooling and heating involve close or direct contact with the human body, for which soft materials, such as cushions, cloths, and flexible foam may be preferred, but these materials cannot withstand the high temperatures of a solder reflow oven.

### SUMMARY

The present disclosure provides solid state heating and cooling devices, systems and methods. Devices, systems and methods provided herein may be used in thermoelectric modules.

In some embodiments, a size of a thermoelectric module in three dimensions may be configured to match an environment of the thermoelectric module. The thermoelectric module may be compressible in thickness.

Other patent applications describe a method for distributing thermoelectric elements into an insulating layer connected by conductors that are expanded on either side of the insulator.

In these previous patent applications, a thermoelectric string is described as a common part that may be inserted into the top layer of a surface in order to add heating and cooling to that surface. The thermoelectric string consists of thermoelectric chips or elements mounted on a strain relief, with conductors emanating upwards to the surface to insert or remove heat via, and other conductors emanating downwards to a heat exchanger layer. The conductors may be stranded wires, for example, which allow for expansion of the strands on the surface and/or the heat exchanger. Such expansion increases the surface area available for conducting heat on the object or person resting on the surface, and also increases the surface area for heat exchange via fluid flow or other approaches.

These previous patent applications also describe the use of flexible circuits to accomplish the electrical connections and thermal interfaces wherein the flexible circuit substitutes for the stranded wires.

The present disclosure provides a distributed thermoelectric module that has flexibility in all three physical dimensions as well as compressibility for vibrational environments and pressurized thermal connections.

In an aspect, the present disclosure provides a thermoelectric device, comprising a container with thermal interfaces for conducting heat; a flexible panel in the container, wherein the flexible panel comprises an electrically and thermally insulating material; and a flexible circuit board in the flexible panel, wherein the flexible circuit board comprises a plurality of thermoelectric modules each comprising a plurality of thermoelectric elements mounted on rigid strain relief elements in the flexible panel, wherein the plurality of thermoelectric elements comprises an n-type thermoelectric element and a p-type thermoelectric element electrically coupled to one another in series, and wherein the flexible circuit board has a Young's modulus less than or equal to about 4 gigapascals at 25° C.

In some embodiments, the plurality of thermoelectric modules is distributed into rows across the flexible circuit board.

In some embodiments, the flexible circuit board has a Young's modulus that is less than or equal to about 3 gigapascals at 25° C. In some embodiments, the Young's modulus is less than or equal to about 2 gigapascals at 25° C. In some embodiments, the Young's modulus is less than or equal to about 1 gigapascal at 25° C. In some embodiments, the Young's modulus is less than or equal to about 0.8 gigapascals at 25° C.

\In some embodiments, the plurality of thermoelectric elements is mounted on the rigid strain relief elements in the absence of an adhesive. In some embodiments, the plurality of thermoelectric elements is soldered to the rigid strain relief elements.

In some embodiments, a given one of the plurality of thermoelectric elements is mounted on a given one of the rigid strain relief elements. In some embodiments, each of the plurality of thermoelectric modules comprises alternating N-type columns and P-type columns, wherein the N-type columns include a plurality of n-type thermoelectric elements including the n-type thermoelectric element, and wherein the P-type columns include a plurality of p-type thermoelectric elements including the p-type thermoelectric element.

In some embodiments, the flexible circuit board comprises a plurality of thermal interfaces along a side of the flexible circuit board. In some embodiments, the flexible circuit board is removable from the panel.

In some embodiments, the flexible panel comprises foam or a polymeric material. In some embodiments, the polymeric material is polyurethane rubber. In some embodiments, the foam is polyethylene foam or Styrofoam.

In some embodiments, the rigid strain relief elements comprise glass and/or epoxy. In some embodiments, the flexible circuit board comprises a polymeric material. In some embodiments, the polymeric material includes polyimide, mylar, plexiglass or Kapton.

In some embodiments, each of the rigid strain relief elements has a Young's modulus greater than or equal to about 15 gigapascals at 25° C. In some embodiments, each of the rigid strain relief elements has a Young's modulus greater than or equal to about 20 gigapascals at 25° C. In some embodiments, each of the rigid strain relief elements has a Young's modulus greater than or equal to about 30 gigapascals at 25° C. In some embodiments, each of the rigid strain relief elements has a Young's modulus greater than or equal to about 40 gigapascals at 25° C. In some embodiments, each of the rigid strain relief elements has a Young's modulus greater than or equal to about 50 gigapascals at 25° C.

In some embodiments, the rigid strain relief elements are disposed between the plurality of thermoelectric elements.

In some embodiments, a given thermoelectric element of the plurality of thermoelectric elements comprises one or more metallic components that are angled with respect to the individual thermoelectric element. In some embodiments, the one or more metallic components are formed of copper, tin, silver, gold, nickel, platinum, chromium, or a combination thereof. In some embodiments, the one or more metallic components of the given thermoelectric element are electrically coupled to an adjacent thermoelectric element of the plurality of thermoelectric elements. In some embodiments, the one or metallic components permit spring loading against the thermal interfaces.

In some embodiments, the thermoelectric device further comprises one or more metallic plates as thermal interfaces for heat transfer adjacent to the flexible circuit board. In some embodiments, the one or more metallic plates comprise aluminum, copper, or an oxide thereof. In some embodiments, the oxide includes aluminum oxide. In some embodiments, the thermoelectric device further comprises an electrically insulating film between each of the one or more metallic plates and the flexible circuit board. In some embodiments, the electrically insulating film comprises polyimide, aluminum oxide, plastic sheeting, polyurethane sheeting, Kapton, or mylar.

In some embodiments, the thermoelectric device further comprises a lubricant for facilitating adjustments from vibrational motions. In some embodiments, the container includes a frame covering an outer perimeter between the thermal interfaces. In some embodiments, the frame comprises a polymeric material.

In another aspect, a method for heating or cooling a thermal interface comprises (a) activating a thermoelectric device comprising (i) a container with thermal interfaces for conducting heat, which thermal interfaces include the thermal interface; (ii) a flexible panel in the container, wherein the flexible panel comprises an electrically and thermally insulating material; and (iii) a flexible circuit board in the flexible panel, wherein the flexible circuit board comprises a plurality of thermoelectric modules each comprising a plurality of thermoelectric elements mounted on rigid strain relief elements in the flexible panel, wherein the plurality of thermoelectric elements comprises an n-type thermoelectric element and a p-type thermoelectric element electrically coupled to one another in series, and wherein the flexible circuit board has a Young's modulus less than or equal to about 4 gigapascals at 25° C. Next, electrical current is directed through the plurality of thermoelectric elements, thereby subjecting the thermal interface to heating or cooling.

In some embodiments, the method further comprises directing a fluid to the thermal interface. In some embodiments, the fluid is air.

In some embodiments, the Young's modulus is less than or equal to about 1 gigapascal at 25° C.

In some embodiments, the plurality of thermoelectric elements is mounted on the rigid strain relief elements in the absence of an adhesive. In some embodiments, the plurality of thermoelectric elements is soldered to the rigid strain relief elements. In some embodiments, a given one of the plurality of thermoelectric elements is mounted on a given one of the rigid strain relief elements. In some embodiments, each of the plurality of thermoelectric modules comprises alternating N-type columns and P-type columns, wherein the N-type columns include a plurality of n-type thermoelectric elements including the n-type thermoelectric element, and wherein the P-type columns include a plurality of p-type thermoelectric elements including the p-type thermoelectric element.

In some embodiments, each of the rigid strain relief elements has a Young's modulus greater than or equal to about 20 gigapascals at 25° C. In some embodiments, the rigid strain relief elements are disposed between the plurality of thermoelectric elements.

In another aspect, a method for generating power comprises activating a thermoelectric device comprising (i) a container with thermal interfaces for conducting heat, which thermal interfaces include the thermal interface; (ii) a flexible panel in the container, wherein the flexible panel comprises an electrically and thermally insulating material; and (iii) a flexible circuit board in the flexible panel, wherein the flexible circuit board comprises a plurality of thermoelectric modules each comprising a plurality of thermoelectric elements mounted on rigid strain relief elements in the flexible panel, wherein the plurality of thermoelectric elements comprises an n-type thermoelectric element and a p-type thermoelectric element electrically coupled to one another in series, and wherein the flexible circuit board has a Young's modulus less than or equal to about 4 gigapascals at 25° C. Next, heat is directed through the plurality of thermoelectric elements to generate flow of electrical current through the plurality of thermoelectric elements, thereby generating power.

In some embodiments, the Young's modulus is less than or equal to about 1 gigapascal at 25° C.

In some embodiments, the plurality of thermoelectric elements is mounted on the rigid strain relief elements in the absence of an adhesive. In some embodiments, the plurality of thermoelectric elements is soldered to the rigid strain relief elements. In some embodiments, a given one of the plurality of thermoelectric elements is mounted on a given one of the rigid strain relief elements. In some embodiments, each of the plurality of thermoelectric modules comprises alternating N-type columns and P-type columns, wherein the N-type columns include a plurality of n-type thermoelectric elements including the n-type thermoelectric element, and wherein the P-type columns include a plurality of p-type thermoelectric elements including the p-type thermoelectric element.

In some embodiments, each of the rigid strain relief elements has a Young's modulus greater than or equal to about 20 gigapascals at 25° C. In some embodiments, the rigid strain relief elements are disposed between the plurality of thermoelectric elements.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “FIG.” and “FIGs.” herein), of which:

FIG. 1 is a side view of a flexible circuit containing thermoelectric elements that is folded to fit into a module housing to move heat from one thermal interface to another;

FIGS. 2A and 2B show side and top views, respectively, of a flexible circuit containing thermoelectric elements after and prior to being folded and fitted into the module housing;

FIG. 3 shows how the strain reliefs may be situated on the opposite side of the flexible circuit;

FIGS. 4A and 4B show how the copper conductors on the flexible and rigid circuits may be laid out to achieve a desired flow of current and heat in the assembled module;

FIG. 5 shows the rigid circuit strip of copper conductors and thermoelectric elements;

FIG. 6 shows how bent metal clips connect the thermoelectric elements electrically to each other and also connect the thermoelectric elements thermally to the two thermal interfaces;

FIG. 7 shows a side view of the rigid circuit board strip with the bent metal clip angled to form a cantilever spring, and also shows a side view of the rigid circuit board strip with the bent metal clips spring-loaded into a flat position for thermal contact with the module housing;

FIG. 8 shows how multiple rigid circuit board strips are assembled together to form a two dimensional area for moving heat with the cantilever springs in the angled position;

FIG. 9 shows how multiple rigid circuit board strips are assembled together to form a two dimensional area for moving heat with the cantilever springs in the spring-loaded horizontal position;

FIGS. 10A and 10B show a side view of the rigid circuit board strips in both angled and spring-loaded positions further with strips of foam situated between the copper clips;

FIG. 11 shows a fully assembled thermoelectric module of the invention and the prior art thermoelectric module; and

FIG. 12 shows a computer control system that is programmed or otherwise configured to implement devices, systems and methods of the present disclosure.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “adjacent” or “adjacent to,” as used herein, includes ‘next to’, ‘adjoining’, ‘in contact with’, and ‘in proximity to’. In some instances, adjacent components are separated from one another by one or more intervening components.

The present disclosure provides thermoelectric devices that may be applied to heating and/or cooling in various applications, such batteries, electronics, drugs, human or animal fluids, foods, beverages, scientific instruments, or any other object, living or not, that may benefit from a temperature controlled surface. As an alternative, thermoelectric devices of the present disclosure may be used to generate electrical current upon the flow of heat through the thermoelectric devices, thereby generating power.

The present disclosure provides a thermoelectric module that has flexibility to be larger or thicker than prior-art thermoelectric modules wherein the height of the module is limited by the height of the thermoelectric elements and is also limited in length and width by the thermal expansion and contraction stress on the thermoelectric elements. The additional thickness of this invention better separates the hot and cold sides, which reduces thermal back flow and increases efficiency. The larger surface area can be matched the size of surface being cooled or heated, eliminating the need for fluid distribution, and eliminating high concentration of heat on the hot side which is difficult to remove. The module may be manufactured using standard pick-and-place assembly techniques common in the electronics industry. The use of rigid circuit board materials provides strain relief and better reliability and durability considering the fragile nature of thermoelectric chips. The use of flex circuit board materials or metal clips allows for the thermoelectric system to be folded or mounted into a foam-filled container, which is compressible for better thermal connection and ease of insertion between other surfaces. The foam also accommodates vibration or other movement environment at the thermal interfaces.

One example application for the thermoelectric module described here is battery thermal management in an electric vehicle. The module is compressed between a battery and a fluid pipe to the radiator of an electric vehicle, allowing for the battery's temperature to be optimized for best performance.

### Thermoelectric Devices and Methods

An aspect of the present disclosure provides a thermoelectric device. The thermoelectric device can comprise a container with thermal interfaces for conducting heat and a flexible panel in the container. The flexible panel can comprise an electrically and thermally insulating material. The thermoelectric device further comprises a flexible circuit board in the flexible panel. The flexible circuit board can comprise a plurality of thermoelectric modules each comprising a plurality of thermoelectric elements mounted on rigid strain relief elements in the flexible panel. The plurality of thermoelectric elements can comprise an n-type thermoelectric element and a p-type thermoelectric element electrically coupled to one another in series.

The flexible circuit board can have a Young's modulus less than or equal to about 4 gigapascals, 3 gigapascals, 2 gigapascals, 1 gigapascal, 0.9 gigapascals, 0.8 gigapascals, 0.7 gigapascals, 0.6 gigapascals, or 0.5 gigapascals at 25° C. Each of the rigid strain relief elements can have a Young's modulus greater than or equal to about 15 gigapascals, 20 gigapascals, 30 gigapascals, 40 gigapascals, or 50 gigapascals at 25° C. The Young's modulus of the flexible circuit board may be less than that of a rigid strain relief element.

The thermoelectric device can include an electrical bus for directing the flow of electrical current to or from the thermoelectric elements. The electrical bus can be in electrical communication with a computer control system and a power source, such as a battery or a power grid.

The plurality of thermoelectric modules can be distributed into rows across the flexible circuit board. This can enable the modules to be distributed across the flexible circuit board.

The flexible circuit board can be formed of or comprise a polymeric material. In some cases, the polymeric material includes polyimide, mylar, plexiglass or Kapton.

The plurality of thermoelectric elements can be mounted on the rigid strain relief elements in the absence of an adhesive. The plurality of thermoelectric elements can be soldered to the rigid strain relief elements.

A given one of the plurality of thermoelectric elements can be mounted on a given one of the rigid strain relief elements. In some cases, each of the plurality of thermoelectric modules comprises alternating N-type columns and P-type columns, wherein the N-type columns include a plurality of n-type thermoelectric elements including the n-type thermoelectric element, and wherein the P-type columns include a plurality of p-type thermoelectric elements including the p-type thermoelectric element.

The flexible circuit board can comprise a plurality of thermal interfaces along a side of the flexible circuit board. The flexible circuit board can be removable from the panel. As an alternative, the flexible circuit board is not removable from the panel.

The flexible panel can comprise or be formed of foam or a polymeric material. The polymeric material can be polyurethane rubber. The foam can be polyethylene foam or Styrofoam.

The rigid strain relief elements can comprise glass, epoxy, or both. The rigid strain relief elements can be disposed between the plurality of thermoelectric elements.

A given thermoelectric element of the plurality of thermoelectric elements can comprise one or more metallic components (e.g., clip) that are angled with respect to the individual thermoelectric element. This may be used to facilitate heat flow to or from the given one of the thermoelectric elements. The one or more metallic components can be heat fins.

The one or more metallic components can be a plurality of metallic components (e.g., clips). The one or more metallic components can be formed of copper, tin, silver, gold, nickel, platinum, chromium, or a combination thereof. The one or more metallic components of the given thermoelectric element can be electrically coupled (e.g., connected) to an adjacent thermoelectric element of the plurality of thermoelectric elements. This can facilitate flow of heat or current among adjacent thermoelectric elements. The one or metallic components can permit spring loading against the thermal interfaces.

The thermoelectric device can comprise one or more metallic plates as thermal interfaces for heat transfer adjacent to the flexible circuit board. The one or more metallic plates can comprise aluminum, copper, or an oxide thereof. The oxide can include aluminum oxide. The one or more metallic plates can be a plurality of metallic plates, such as at least 2, 3, 4, 5, 6, 7, 8, 9, or 10 plates. The metallic plates can have various shapes or sizes. For example, the metallic plates can be circular, triangular, square or rectangular.

The thermoelectric device can comprise an electrically insulating film between each of the one or more metallic plates and the flexible circuit board. The electrically insulating film can comprises a polymeric material. The electrically insulating film can comprise a polyimide, aluminum oxide, plastic sheeting, polyurethane sheeting, Kapton, or mylar.

The thermoelectric device can further comprise a lubricant to facilitate adjustment from vibrational motions or other disturbances.

The container can include a frame covering an outer perimeter between the thermal interfaces. The frame can provide structural support for the thermoelectric device. The frame can comprise or be formed of a polymeric material. The frame can provide heat flow to the plurality of thermoelectric modules.

Thermoelectric devices of the present disclosure may be used for heating or cooling, or power generation. In another aspect, a method for heating or cooling a thermal interface can comprise (a) activating a thermoelectric device that can comprise (i) a container with thermal interfaces for conducting heat, which thermal interfaces include the thermal interface, (ii) a flexible panel in the container, and (iii) a flexible circuit board in the flexible panel. The flexible panel can comprise an electrically and thermally insulating material. The flexible circuit board can comprise a plurality of thermoelectric modules each comprising a plurality of thermoelectric elements mounted on rigid strain relief elements in the flexible panel. The plurality of thermoelectric elements can comprise an n-type thermoelectric element and a p-type thermoelectric element electrically coupled to one another in series. The flexible circuit board can have a Young's modulus less than or equal to about 4 gigapascals at 25° C. Next, electrical current can be directed through the plurality of thermoelectric elements. This can subject the thermal interface to heating or cooling. As an alternative, heat can be directed through the plurality of thermoelectric elements to generate a flow of electrical current through the plurality of thermoelectric elements, thereby generating power. The power can be directed to a load (e.g., vehicle electrical system or power grid), or stored in an energy storage unit, such as a battery.

The method can comprise directing a fluid to the thermal interface. The fluid can be a heat transfer medium, such as convective heat transfer medium. The fluid can be a gas or liquid. The fluid can be air. The fluid can be directed using a mechanical device, such as a fan or pump.

The present disclosure also provides thermoelectric system that can include one or more thermoelectric devices. The one or more thermoelectric devices can be as described above or elsewhere herein. The thermoelectric system can include a computer control system.

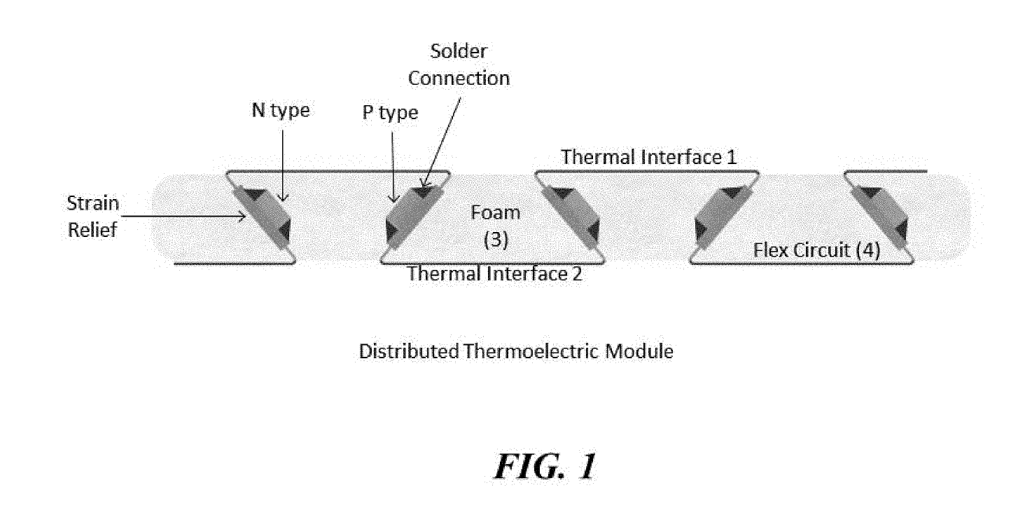

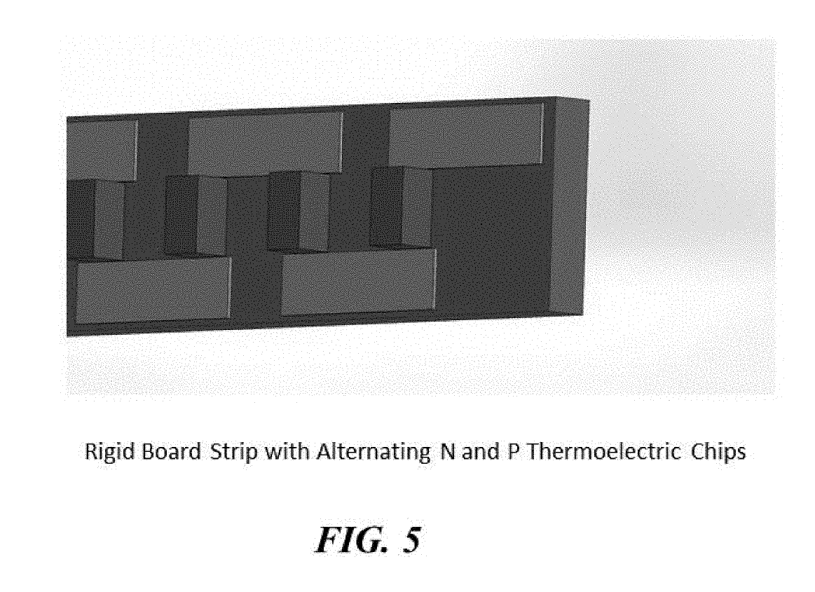

FIGS. 1-4 show a first preferred embodiment of the invention that combines flexible and rigid circuits. FIGS. 5-10 shows a second preferred embodiment of the invention that combines rigid circuits with bendable and springy metal clips.

In FIG. 1, a distributed thermoelectric module is comprised of a flexible circuit 4 folded in and out of a foam insulating substrate 3. The flexible circuit is comprised of copper foil and a flexible insulator such as Kapton, polyimide, mylar, or similar material. The foam is comprised of polyurethane foam, rubber, polyethylene foam, Styrofoam, or other similar material. The N-type elements 1 and P-type elements 2 allows for current to flow in alternating directions (elements connected in series) while insuring that the heat moves in one direction from one thermal interface 6 to another thermal interface 7. The elements are mounted on strain reliefs 5 to protect them from cracking and from delamination of the solder connections 8. The strain reliefs could be glass, epoxy, a combination of fiberglass and epoxy, or other rigid circuit board material. The angled positioning of the rigid portions 5 combined with the foam substrate 3 allows these contents of the module to be compressed between the top 6 and bottom 7 for fitment into cavities between an object to the heated/cooled and a heat exchanger.

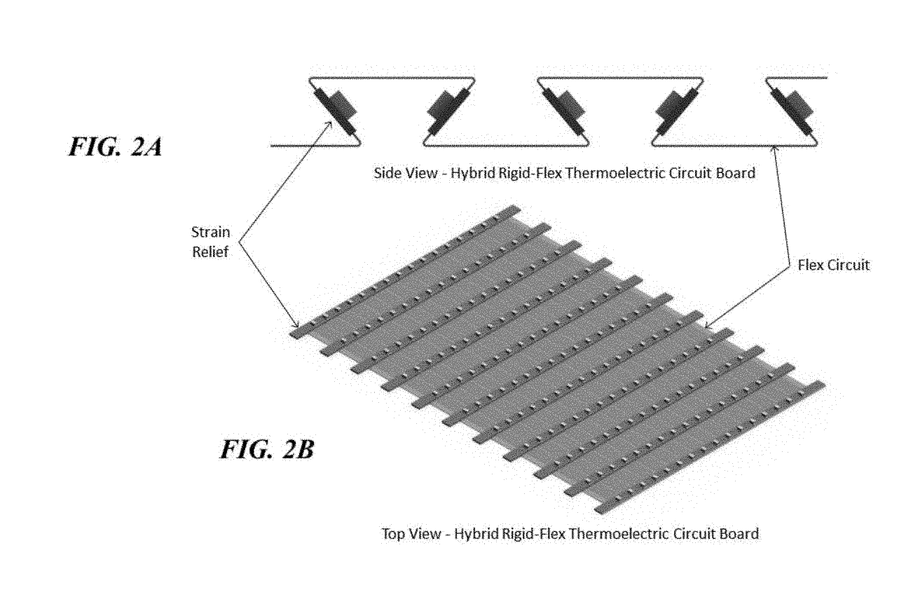

FIG. 2A shows the distributed thermoelectric module of FIG. 1 with the foam removed, as the foam is not necessary in some applications. FIG. 2B shows the thermoelectric circuit board of FIG. 1 and FIG. 2A unfolded and flat. The strain relief 5 is a rigid circuit board material such as FR4, which is comprised of glass fiber embedded in epoxy. In FIG. 2B, the rigid circuit boards 5 are adhered on top of a flexible circuit board 4 (“Flex Circuit”). The thermoelectric elements 1 and 2 are mounted on the strain relief boards and soldered to copper pads on these rigid boards.

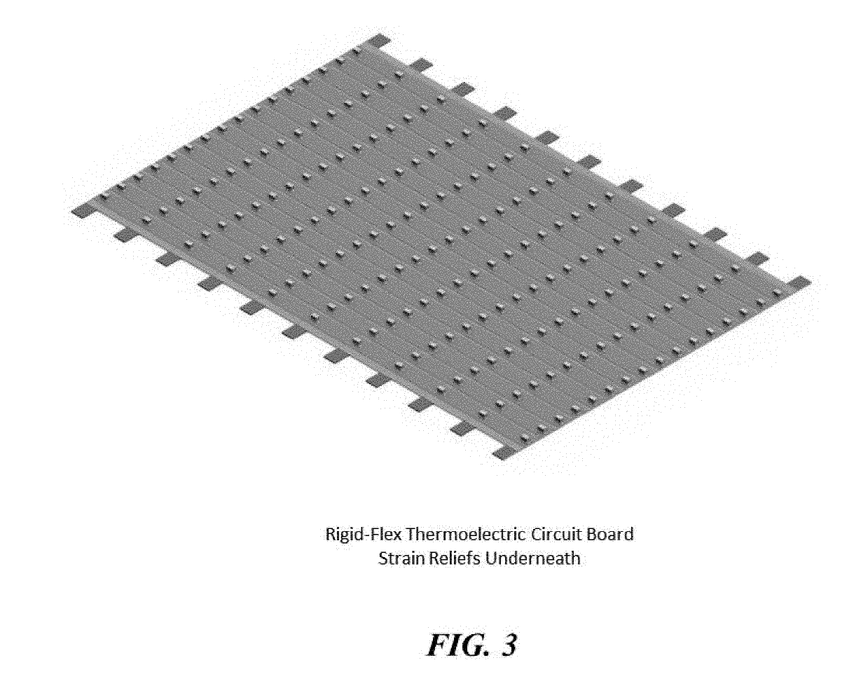

FIG. 3 shows an alternative placement wherein the rigid boards 5 are mounted and adhered underneath the flexible circuit.

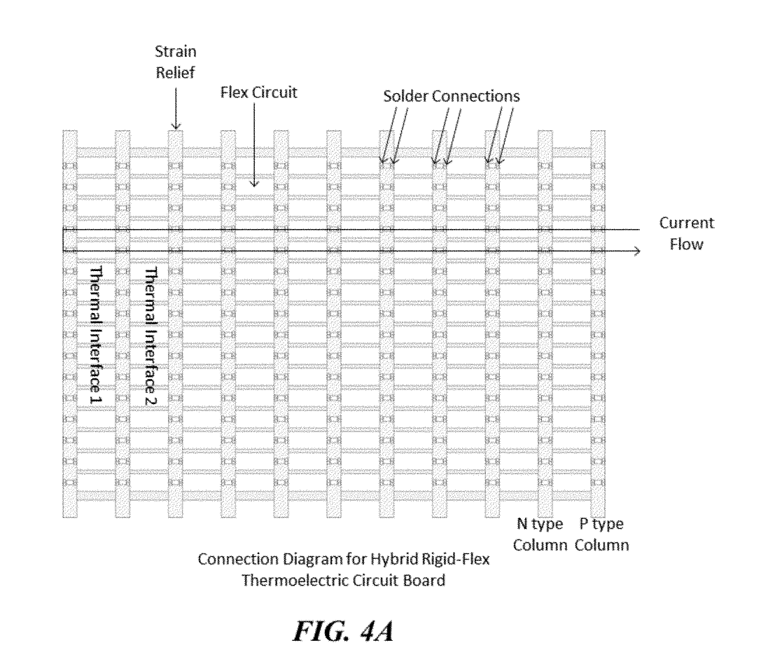

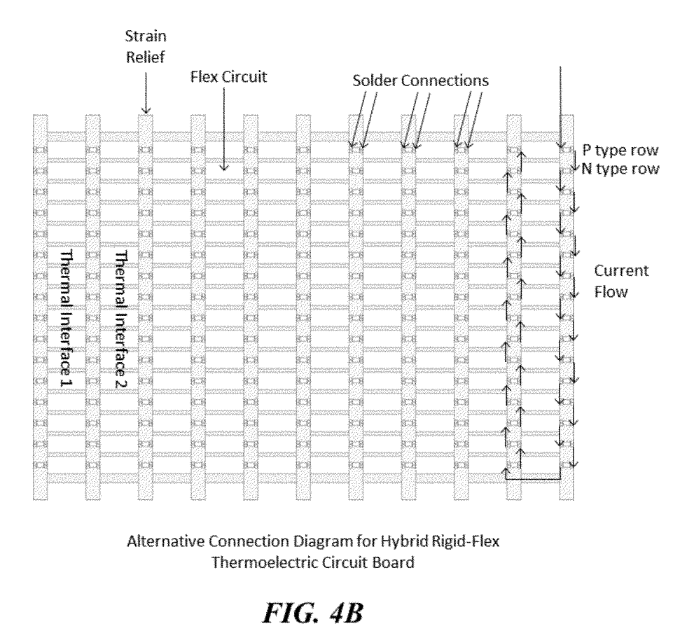

FIG. 4A shows how the conductor portion of the rigid circuit boards 5 can appropriately route the electric current to achieve a hot side and a cold side when the thermoelectric module of FIGS. 1-3 are energized. Here, the elements are soldered to conductive paths on the rigid boards, and those conductive paths are connected to conductive paths on the flexible circuit board. By applying a voltage across the beginning and end of the “Current Flow” path 9, the electric current will flow in the direction of the arrow. As the current flows through alternating N type element 1 and P type elements 2 in the columns, the flexible portions 4 between the rigid boards become alternately warm and cold. When the board in FIG. 4A is folded into the configuration of FIG. 1, all of the warm portions are on the top and all of the cold portions are on the bottom, creating a thermoelectric module. The length of the two planar dimensions of this module are configurable by appropriately spacing apart the thermoelectric elements on the rigid boards and by spacing apart the rigid boards themselves. The thickness of this module is configurable by the spacing apart and the angle the rigid boards.

FIG. 4B shows an alternative method for routing the electrical current. The current flow 10 follows a path down the odd-numbered rigid boards and up the even rigid boards. While flowing along a column, the current moves heat through alternating N type elements 1 and P type elements 2. The Peliter effect of the chips causes the flexible portions 6 and 7 of the board to become alternately warm and cool. In this configuration, the flexible board conductive paths are primarily heat exchangers, except for at the ends of the rigid boards wherein the flexible conductive path 13, in addition, electrically connect one rigid board to the next one.

The conductor routing of FIG. 4A and FIG. 4B is possible with either the configuration of FIG. 2B or FIG. 3 if through-vias are used to connect the conductive paths of the rigid circuit boards with the conductive paths of the flexible circuit board in order to achieve the current flow shown in FIG. 4A and FIG. 4B.

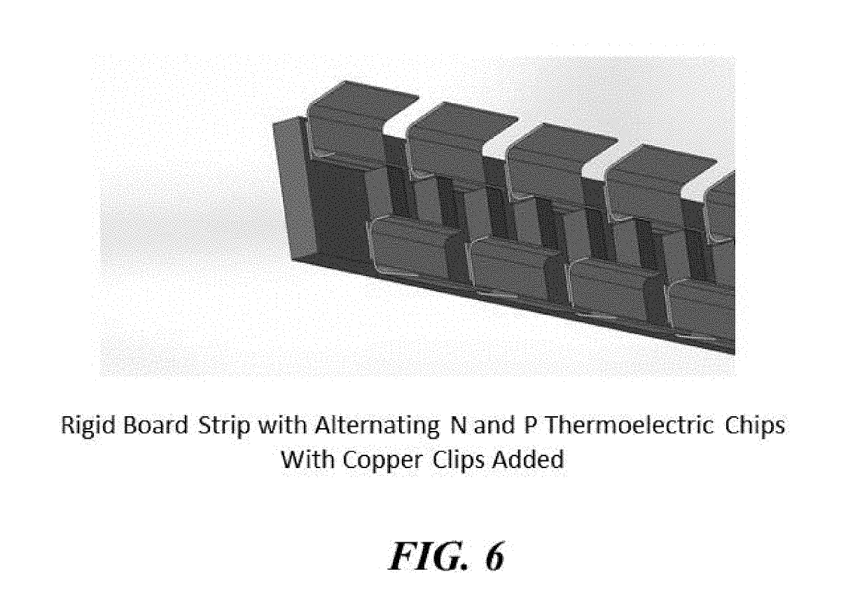

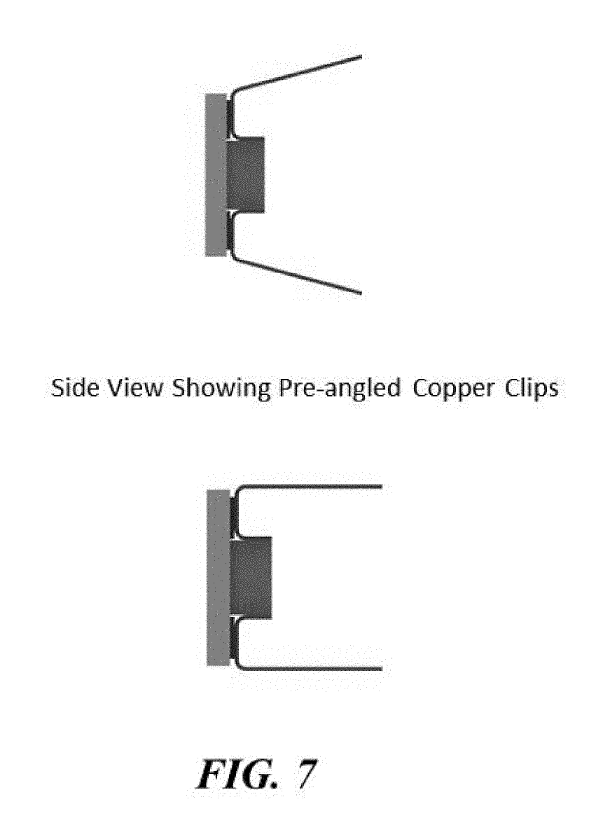

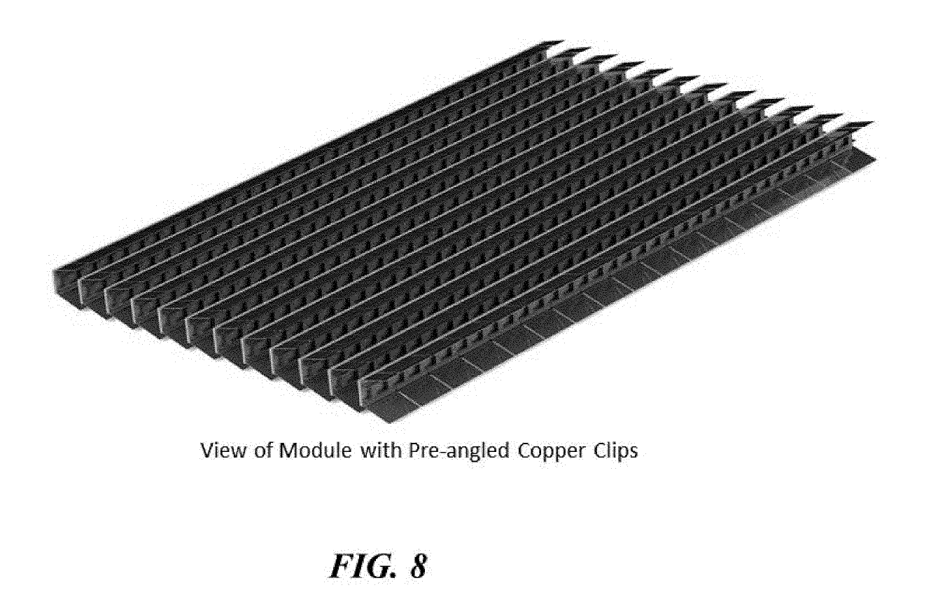

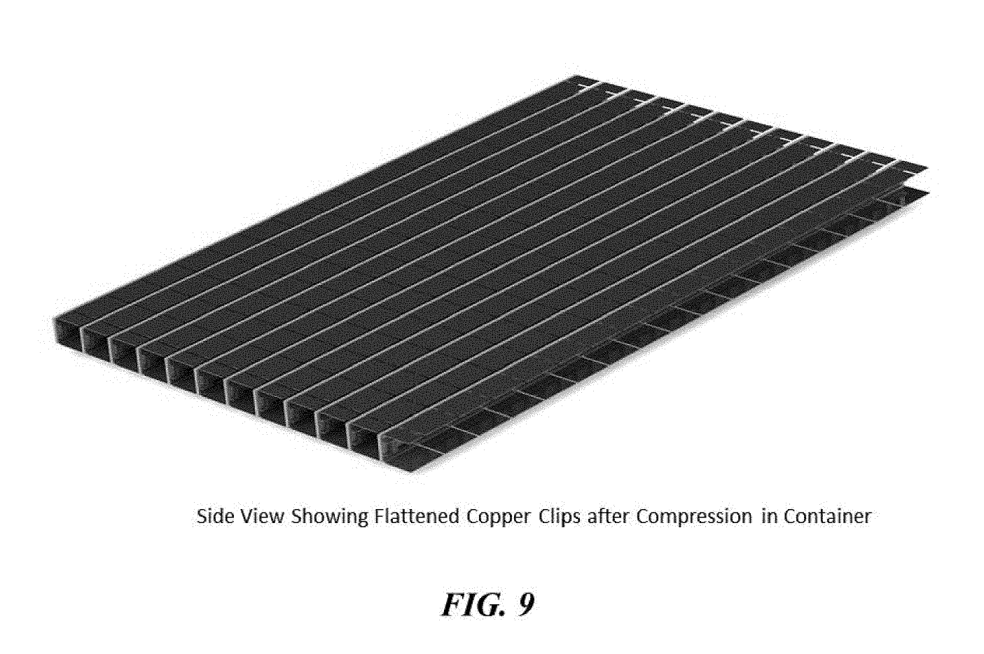

FIGS. 5-10 show a second embodiment of the invention. In this embodiment, the current flows along the rigid circuit board strips as indicated in FIG. 4B. FIG. 5 shows the connecting pads 15 on the rigid strip. FIG. 6 shows how metal “clips” 11 and 12 are added. The metal may be formed of copper, gold, silver, and alloy of these, or other metal or metal alloy with thermal and electrical conductivities suitable for use in thermoelectric modules and devices. This metal may also be coated with tin, gold, or other coating to prevent or slow corrosion or oxidation. The metal may also be alloyed with chrome, nickel, or any combination or alloy of these or similar metal in order to increase strength or modify the spring constant. The clips provide greater metal-to-chip contact area than the prior flexible circuit embodiment, and hence improve the thermal conduction from the end of the elements 1 and 2. The clips 12 in FIG. 6 and the pads 15 in FIG. 5 also provide the current flow illustrated in FIG. 4B. FIG. 7 shows a profile view of end of the rigid circuit board strip. The clips 11 and 12 are formed to have an obtuse angle relative to the board 5. This obtuse angle becomes a right angle as shown in FIG. 7b when the strip is placed in a container (not shown in FIG. 7) between its top and bottom plates. The obtuse angle becoming 90 degrees provides some spring force of the clips 11 and 12 against the upper and lower plates, improving thermal contact. The spring load also allow for conformance of the clip's surface against the plate. FIGS. 8 and 9 show a plurality of strips 14 arranged to be the internal contents of a thermoelectric module, with the initial obtuse angle and the spring-loaded right angle, respectively.

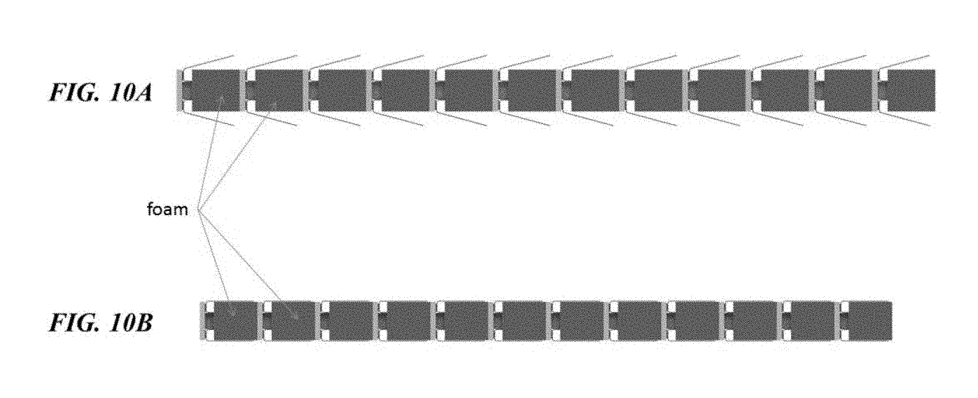

FIGS. 10A and 10B show an edge view of the strips 14 with foam 3 inserted between the strips providing several benefits, including additional insulation, prevention of heat backflow via convection, greater mechanical stability, additional compliance of strips and of the clips, and finally to allow parts inside the module to shift during thermal expansion and contraction. FIG. 10A is a side view of strips showing foam insulation with copper clips pre-angled. FIG. 10B shows the clips compressed after insertion into the container.

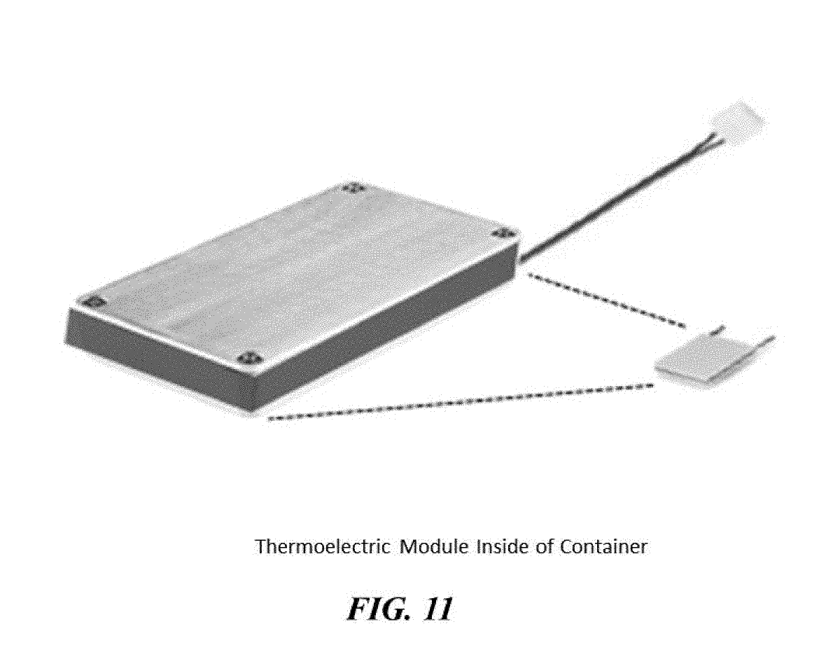

FIG. 11 shows the fully assembled module 20 of the invention after the components are placed in a container. The container includes and upper plate 24 and a lower plate 25, where heat is moved from one plate to the other. The plates are made from a sturdy material with good thermal conductivity such as aluminum, copper, or aluminum oxide. Each plate may have an electrically insulating layer on the inner side to prevent electrical shorts. This electrically insulating layer may be made from Kapton, polyimide, mylar, or aluminum oxide or other oxide. The plates are supported by a frame 26, which protects the interior contents and also may be compliant to allow compressibility. The frame may be made from plastic, foam, polyurethane foam, polyethylene foam, Styrofoam, rubber, rubberized foam, silicone, glass-reinforced epoxy laminate (e.g., FR4), epoxy, glass-reinforced epoxy, or similar material. The module is energized by a voltage applied to a connector 22 and wires 23. For reference, a prior-art thermoelectric module 21 is also illustrated in FIG. 11.

### Computer Control Systems

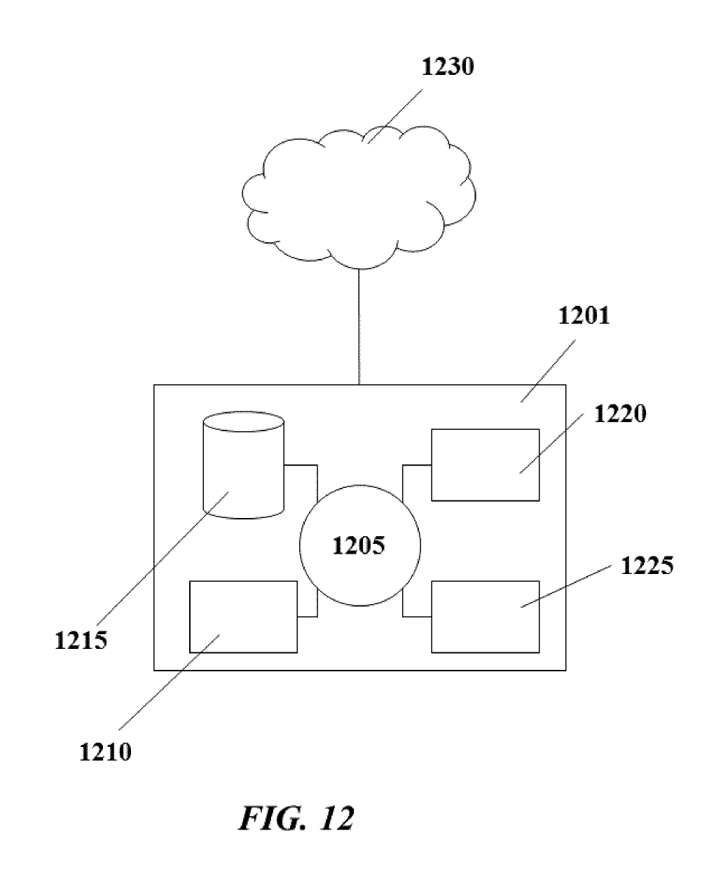

The present disclosure provides computer control systems that are programmed to implement methods of the disclosure. FIG. 12 shows a computer system 1201 that is programmed or otherwise configured to control thermoelectric devices and systems of the present disclosure. The computer system 1201 includes a central processing unit (CPU, also “processor” and “computer processor” herein) 1205, which can be a single core or multi core processor, or a plurality of processors for parallel processing. The computer system 1201 also includes memory or memory location 1210 (e.g., random-access memory, read-only memory, flash memory), electronic storage unit 1215 (e.g., hard disk), communication interface 1220 (e.g., network adapter) for communicating with one or more other systems, and peripheral devices 1225, such as cache, other memory, data storage and/or electronic display adapters. The memory 1210, storage unit 1215, interface 1220 and peripheral devices 1225 are in communication with the CPU 1205 through a communication bus (solid lines), such as a motherboard. The storage unit 1215 can be a data storage unit (or data repository) for storing data. The computer system 1201 can be operatively coupled to a computer network (“network”) 1230 with the aid of the communication interface 1220. The network 1230 can be the Internet, an internet and/or extranet, or an intranet and/or extranet that is in communication with the Internet. The network 1230 in some cases is a telecommunication and/or data network. The network 1230 can include one or more computer servers, which can enable distributed computing, such as cloud computing. The network 1230, in some cases with the aid of the computer system 1201, can implement a peer-to-peer network, which may enable devices coupled to the computer system 1201 to behave as a client or a server.

The CPU 1205 can execute a sequence of machine-readable instructions, which can be embodied in a program or software. The instructions may be stored in a memory location, such as the memory 1210. The instructions can be directed to the CPU 1205, which can subsequently program or otherwise configure the CPU 1205 to implement methods of the present disclosure. Examples of operations performed by the CPU 1205 can include fetch, decode, execute, and writeback.

The CPU 1205 can be part of a circuit, such as an integrated circuit. One or more other components of the system 1201 can be included in the circuit. In some cases, the circuit is an application specific integrated circuit (ASIC).

The storage unit 1215 can store files, such as drivers, libraries and saved programs. The storage unit 1215 can store user data, e.g., user preferences and user programs. The computer system 1201 in some cases can include one or more additional data storage units that are external to the computer system 1201, such as located on a remote server that is in communication with the computer system 1201 through an intranet or the Internet. The computer system 1201 can communicate with one or more remote computer systems through the network 1230.

Methods as described herein can be implemented by way of machine (e.g., computer processor) executable code stored on an electronic storage location of the computer system 1201, such as, for example, on the memory 1210 or electronic storage unit 1215. The machine executable or machine readable code can be provided in the form of software. During use, the code can be executed by the processor 1205. In some cases, the code can be retrieved from the storage unit 1215 and stored on the memory 1210 for ready access by the processor 1205. In some situations, the electronic storage unit 1215 can be precluded, and machine-executable instructions are stored on memory 1210.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 1201, can be embodied in programming Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1.-54. (canceled)

55. A thermoelectric device, comprising:
a container with thermal interfaces for conducting heat;
a flexible panel in said container, wherein said flexible panel comprises an electrically and thermally insulating material; and
a flexible circuit board in said flexible panel, wherein said flexible circuit board comprises a plurality of thermoelectric modules each comprising a plurality of thermoelectric elements mounted on rigid strain relief elements in said flexible panel, wherein said plurality of thermoelectric elements comprises an n-type thermoelectric element and a p-type thermoelectric element electrically coupled to one another in series, and wherein said flexible circuit board has a Young's modulus less than or equal to about 4 gigapascals at 25° C.

56. The thermoelectric device of claim 55, wherein said plurality of thermoelectric modules is distributed into rows across said flexible circuit board.

57. The thermoelectric device of claim 55, wherein said plurality of thermoelectric elements is mounted on said rigid strain relief elements in the absence of an adhesive or by soldering said plurality of thermoelectric elements to said rigid strain relief elements.

58. The thermoelectric device of claim 55, wherein a given one of said plurality of thermoelectric elements is mounted on a given one of said rigid strain relief elements.

59. The thermoelectric device of claim 55, wherein each of said plurality of thermoelectric modules comprises alternating N-type columns and P-type columns, wherein said N-type columns include a plurality of n-type thermoelectric elements including said n-type thermoelectric element, and wherein said P-type columns include a plurality of p-type thermoelectric elements including said p-type thermoelectric element.

60. The thermoelectric device of claim 55, wherein said flexible circuit board comprises a plurality of thermal interfaces along a side of said flexible circuit board.

61. The thermoelectric device of claim 55, wherein said flexible circuit board is removable from said panel.

62. The thermoelectric device of claim 55, wherein said flexible panel comprises foam or a polymeric material.

63. The thermoelectric device of claim 55, wherein said rigid strain relief elements comprise glass and/or epoxy.

64. The thermoelectric device of claim 55, wherein said flexible circuit board comprises a polymeric material.

65. The thermoelectric device of claim 55, wherein each of said rigid strain relief elements has a Young's modulus greater than or equal to about 15 gigapascals at 25° C.

66. The thermoelectric device of claim 55, wherein said rigid strain relief elements are disposed between said plurality of thermoelectric elements.

67. The thermoelectric device of claim 55, wherein a given thermoelectric element of said plurality of thermoelectric elements comprises one or more metallic components that are angled with respect to said given thermoelectric element.

68. The thermoelectric device of claim 67, wherein said one or more metallic components of said given thermoelectric element are electrically coupled to an adjacent thermoelectric element of said plurality of thermoelectric elements.

69. The thermoelectric device of claim 67, wherein said one or metallic components permit spring loading against said thermal interfaces.

70. The thermoelectric device of claim 55, further comprising one or more metallic plates as thermal interfaces for heat transfer adjacent to said flexible circuit board.

71. The thermoelectric device of claim 70, further comprising an electrically insulating film between each of said one or more metallic plates and said flexible circuit board.

72. The thermoelectric device of claim 55, further comprising a lubricant for facilitating adjustments from vibrational motions.

73. The thermoelectric device of claim 55, wherein said container includes a frame covering an outer perimeter between said thermal interfaces.

74. The thermoelectric device of claim 55, wherein said frame comprises a polymeric material.

75. A method for heating or cooling a thermal interface, comprising:
(a) activating a thermoelectric device comprising (i) a container with thermal interfaces for conducting heat, which thermal interfaces include said thermal interface; (ii) a flexible panel in said container, wherein said flexible panel comprises an electrically and thermally insulating material; and (iii) a flexible circuit board in said flexible panel, wherein said flexible circuit board comprises a plurality of thermoelectric modules each comprising a plurality of thermoelectric elements mounted on rigid strain relief elements in said flexible panel, wherein said plurality of thermoelectric elements comprises an n-type thermoelectric element and a p-type thermoelectric element electrically coupled to one another in series, and wherein said flexible circuit board has a Young's modulus less than or equal to about 4 gigapascals at 25° C.; and
(b) directing electrical current through said plurality of thermoelectric elements, thereby subjecting said thermal interface to heating or cooling.

76. The method of claim 75, further comprising directing a fluid to said thermal interface.

77. The method of claim 75, wherein said plurality of thermoelectric elements is mounted on said rigid strain relief elements in the absence of an adhesive or by soldering said plurality of thermoelectric elements to said rigid strain relief elements.

78. The method of claim 75, wherein each of said plurality of thermoelectric modules comprises alternating N-type columns and P-type columns, wherein said N-type columns include a plurality of n-type thermoelectric elements including said n-type thermoelectric element, and wherein said P-type columns include a plurality of p-type thermoelectric elements including said p-type thermoelectric element.

79. The method of claim 75, wherein each of said rigid strain relief elements has a Young's modulus greater than or equal to about 20 gigapascals at 25° C.
